(19) United States
(12) Patent Application Publication
(10) Pub. No.: US 2015/0373830 A1
(43) Pub. Date: Dec. 24, 2015

(54) COMPOSITE SUBSTRATE INCLUDING FOLDABLE PORTION

(71) Applicant: Kabushiki Kaisha Toshiba, Tokyo (JP)

(72) Inventors: Shigenori Miyagawa, Ome Tokyo (JP); Daisuke Maehara, Ome Tokyo (JP)

(21) Appl. No.: 14/665,772

(22) Filed: Mar. 23, 2015

Related U.S. Application Data
(60) Provisional application No. 62/014,412, filed on Jun. 19, 2014.

(51) Int. Cl. H05K 1/02

(52) U.S. Cl. CPC H05K 1/028; H05K 1/0298; H05K 2201/055; H05K 2201/056

(57) ABSTRACT

According to one embodiment, a composite substrate includes a soft layer, a hard layer, a rigid portion and a flexible portion. The soft layer includes a first conductor layer with a conductor pattern and a first flexible insulating layer. The hard layer includes a second conductor layer with a conductor pattern and a second rigid insulating layer. The rigid portion is formed by laminating the soft layer and the hard layer. The flexible portion includes a transition portion which is in proximity to the rigid portion by extending the soft layer and is wider than an interconnect portion.

### CROSS-REFERENCE TO RELATED APPLICATIONS

This application claims the benefit of U.S. Provisional Application No. 62/014,412, filed Jun. 19, 2014, the entire contents of which are incorporated herein by reference.

### FIELD

Embodiments described herein relate generally to composite substrate including a foldable portion for assembling into a casing.

### BACKGROUND

A substrate for an electronic circuit in a small electronic device such as a wearable device sometimes has to be folded and built in for arrangement of electronic components depending on the shape of a housing or operability of the electronic device. There is a composite substrate which comprises both a rigid portion in which electronic components are mounted and a flexible portion to be bent for connecting between rigid portions. When the composite substrate is built into a housing, it is folded in the flexible portion. Since hardness in a boundary portion between the rigid portion and the flexible portion discontinuously changes, stress easily concentrates in the flexible portion when the boundary portion is bent. As a result, a conductor pattern formed in the flexible portion of the composite substrate may be disconnected, and an insulating layer of the flexible portion may be cracked. A composite substrate with a structure in which the flexible portion in the boundary portion of hardness of the composite substrate does not get easily damaged is desired.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is a perspective view of a composite substrate according to a first embodiment.

FIG. 2 is a partial sectional view of the composite substrate taken along line F2-F2 in FIG. 1.

FIG. 3 is a plan view of a first conductor pattern of a composite substrate according to a second embodiment.

FIG. 4 is a plan view of a second conductor pattern laminated on the first conductor pattern in FIG. 3.

FIG. 5 is a perspective view with a flexible portion of a composite substrate according to a third embodiment bent.

FIG. 6 is a perspective view of the composite substrate from the perspective of the direction of arrow F6 in FIG. 5.

FIG. 7 is a partial sectional view of the composite substrate taken along line F7-F7 in FIG. 5.

FIG. 8 is a partial sectional view of the composite substrate taken along line F8-F8 in FIG. 5.

FIG. 9 is a perspective view with a flexible portion of a composite substrate according to a fourth embodiment bent in a casing.

### DETAILED DESCRIPTION

Various embodiments will be described hereinafter with reference to the accompanying drawings.

In general, according to one embodiment, a composite substrate comprises a soft layer, a hard layer, a rigid portion and a flexible portion. The soft layer comprises a first conductor layer with a conductor pattern and a first flexible insulating layer. The hard layer comprises a second conductor layer with a conductor pattern and a second rigid insulating layer. The rigid portion is formed by laminating the soft layer and the hard layer. The flexible portion comprises a transition portion which is in proximity to the rigid portion by extending the soft layer away from an outer peripheral edge of the rigid portion and is wider along the outer peripheral edge of the rigid portion than an interconnect portion apart from the rigid portion.

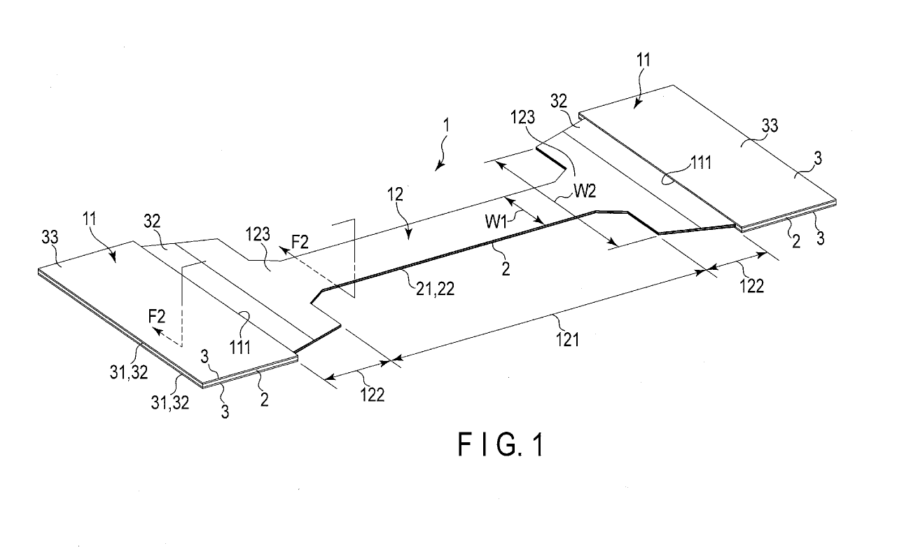

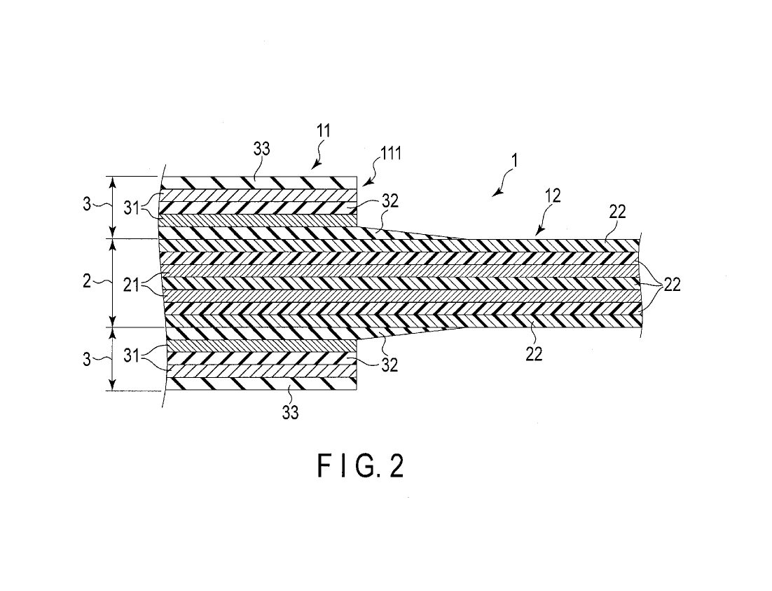

A composite substrate 1 according to a first embodiment will be described with respect to FIGS. 1 and 2. The composite substrate 1 is a so-called “rigid flexible substrate” formed of a rigid portion 11 in which a soft layer 2 and a hard layer 3 are laminated, and a flexible portion 12 formed of the soft layer 2 extending from the rigid portion 11. In this embodiment, FIG. 1 shows the composite substrate 1 in which two rigid portions 11 are connected by the flexible portion 12.

The soft layer 2 comprises a first conductor layer 21 with a conductor pattern and a first insulating layer 22 with flexibility. In this embodiment, as shown in FIG. 2, two first conductor layers 21 and three first insulating layers 22 are provided to be alternately laminated. The first conductor layer 21 is formed of metallic foil, in this embodiment, of copper foil, and the first insulating layer 22 is formed of insulating resin film with flexibility, in this embodiment, of polyimide film. The outermost surface of the soft layer 2 is covered with the polyimide film.

The hard layer 3 comprises a second conductor layer 31 with a conductor pattern and a second insulating layer 32 with rigidity. In this embodiment, the hard layers 3 are bonded to both sides of the soft layer 2. In the composite substrate 1 shown in FIG. 2, each of the hard layers 3 is formed by alternately laminating two second conductor layers 31 and two second insulating layers 32. The second conductor layer 31 is formed by metallic foil, in this embodiment, of copper foil, and the second insulating layer 32 is formed of insulating resin with rigidity, in this embodiment, of epoxy resin containing a glass cloth.

Furthermore, an outermost layer 33 which is a surface layer of the hard layer 3 is a solder resist layer. The rigid portion 11 comprises a through-hole and a via transversely connecting the first conductor layer 21 and the second conductor layer 31 in a laminate thickness direction as shown in FIG. 2.

The flexible portion 12 comprises an interconnect portion 121 and a transition portion 122 as shown in FIG. 1. The interconnect portion 121 is a portion apart from the rigid portion 11, in this case, a section between two rigid portions 11. The transition portion 122 is formed in the proximity of an outer peripheral edge 111 of the rigid portion 11, and comprises width W2 greater than width W1 of the interconnect portion 121 in a width direction along the outer peripheral edge 111. Accordingly, the flexible portion 12 formed of the soft layer 2 extending from the outer peripheral edge 111 of the rigid portion 11 is softer and easier to bend in the interconnect portion 121 than in the transition portion 122.

Also, the second insulating layer 32 laminated just outside the soft layer 2 in the rigid portion 11 extends to cover part of the transition portion 122, that is, a vicinity of the outer peripheral edge 111 of the rigid portion 11 across the outer peripheral edge 111 of the rigid portion 11. The second insulating layer 32 comprises a glass cloth and high rigidity. Reinforcement is performed at the outer peripheral edge 111 of the rigid portion 11 to prevent the flexible portion 12 from being folded. Also, the length from the outer peripheral edge 111 of the rigid portion 11 to a boundary portion 123 between the interconnect portion 121 and the transition portion 122, that is, the length of the transition portion 122 is longer than that of an area in which the second insulating layer 32 extending from the rigid portion 11 covers the flexible portion 12.

In addition, width W2 of the transition portion 122 gradually narrows towards the interconnect portion 121. Also, the boundary portion 123 between the transition portion 122 and the interconnect portion 121 is formed to gradually widen from the interconnect portion 121 towards the transition portion 122 for smooth connection to the transition portion 122. As a result, the strength of the soft layer 2 in the boundary portion 123 between the interconnect portion 121 and the transition portion 122 does not discontinuously change. Since stress does not concentrate when the flexible portion 12 is folded, a conductor pattern of the first conductor layer 21 of the flexible portion 12 is not disconnected, or the first insulating layer 22 is not cracked.

Regarding the transition portion 122, each of the size of a width direction along the rigid portion 11 and the size of a direction away from the outer peripheral edge 111 of the rigid portion 11 is set in order for the flexible portion 12 to be folded at a position farther apart from the outer peripheral edge 111 of the rigid portion 11 than the length approximately twice the minimum bend radius allowed for the soft layer 2 when the flexible portion 12 is folded with respect to the rigid portion 11.

In this embodiment, width W2 of the transition portion 122 is approximately two or three times greater than width W1 of the interconnect portion 121. If the composite substrate 1 is folded to be built into a casing, etc., it is easy to fold in the boundary portion 123 between the interconnect portion 121 and the transition portion 122. Both the interconnect portion 121 and the transition portion 122 are the soft layer 2 comprising the same thickness, and are the flexible portion 12. Since substantially the same stress is applied to both of them when they are bent, conductor patterns of their first conductor layers 21 are both kept connected and never broken at one side, and no crack is made on either of the insulating films of their first insulating layers 22.

Each of the composite substrates 1 of second to fourth embodiments will be hereinafter described with respect to each of the figures. In each embodiment, structures comprising the same function as the composite substrate 1 of the first embodiment will be denoted in the description and figures by the same reference numbers, and the description of the first embodiment will be taken into consideration for their detailed explanations.

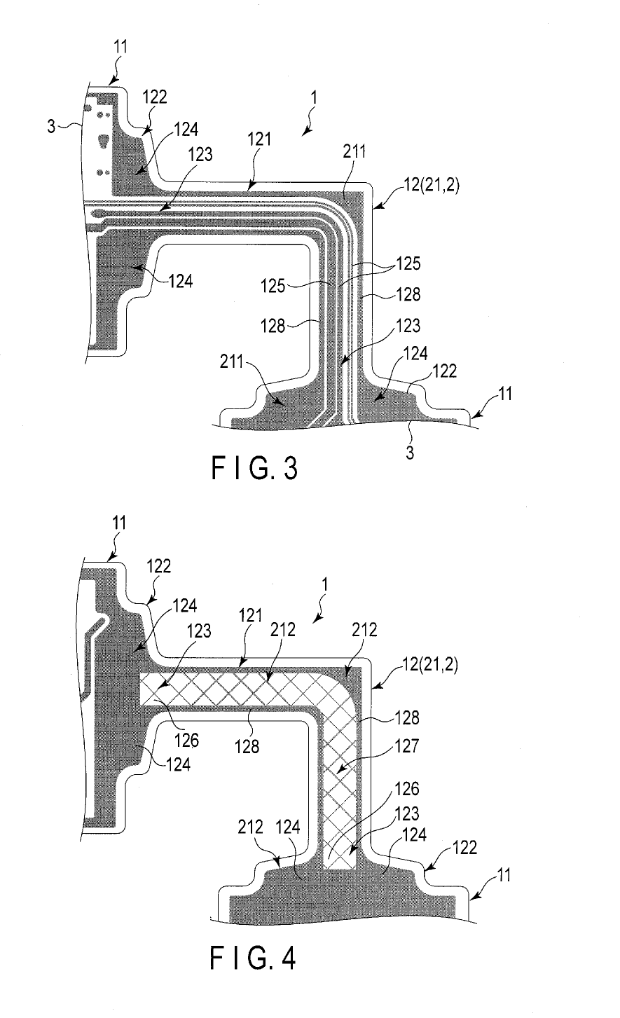

The composite substrate 1 according to the second embodiment will be described with respect to FIGS. 3 and 4. FIG. 3 is a plan view of a first conductor pattern 211 included in the first conductor layer 21 of the soft layer 2 of the composite substrate 1. FIG. 4 is a plan view of a second conductor pattern 212 included in the first conductor layer 21 of the soft layer 2 of the composite substrate 1. The first conductor pattern 211 and the second conductor pattern 212 are laminated, and the first insulating layer 22 is inserted therebetween as well as in the first embodiment. Also, in this embodiment, the interconnect portion 121 of the flexible portion 12 is formed into a so-called elbow shape which is obtained by substantially orthogonally bended shape along a laminated plane in the middle of its length. It can be a straight line as in the first embodiment.

As shown in FIGS. 3 and 4, each transition portion 122 comprises a reinforcing pattern 124 which is a conductor pattern formed continuously from the rigid portion 11. The reinforcing patterns 124 are created together with the first conductor pattern 211 and the second conductor pattern 212 simultaneously with an interconnect pattern of each layer. Since the reinforcing pattern 124 is provided, an advantage similar to that obtained by a structure in which a reinforcing member is provided on the soft layer 2 is obtained, that is, rigidity of the transition portion 122 increases. In particular, the rigidity in the proximity of the outer peripheral edge 111 of the rigid portion 11 increases by continuously forming the reinforcing pattern 124 from the rigid portion 11. Then, if the composite substrate 1 is folded in the flexible portion 12, it is prevented from being carelessly folded at the outer peripheral edge 111 of the rigid portion 11.

As shown in FIG. 3, the first conductor pattern 211 of the flexible portion 12 forms a signal line 125 connected to an electronic component on the rigid portion 11. In this embodiment, the signal line 125 connects between the rigid portions 11 in parallel each other at intervals predetermined in accordance with current or voltage to be applied to the interconnect portion 121. Also, as shown in FIG. 4, the second conductor pattern 212 of the flexible portion 12 comprises a low-strength portion 126 with lower pattern density than the first conductor pattern 211 in the transition portion 122 connected to an interconnect portion 14.

In the second embodiment, as shown in FIG. 4, the second conductor pattern 212 comprises conductivity throughout the interconnect portion 121, and comprises a low-strength area 127 with lower pattern density than a portion corresponding to the rigid portion 11. In this embodiment, the low-strength area 127 is connected to the low-strength portion 126. That is, the low-strength portion 126 is extended and formed in order for the low-strength area 127 to be in part of the transition portion 122. Also, in this embodiment, the second conductor patterns 212 of the low-strength area 127 and the low-strength portion 126 are formed into a slanted lattice shape with respect to a direction where the signal line 125 extends. It should be noted that the second conductor patterns 212 of the low-strength area 127 and the low-strength portion 126 function as a ground for the signal line 125. Since it is formed into a lattice shape, even if disconnection occurs, a disconnected portion can be supplemented by applying current in another portion.

Also, as shown in FIGS. 3 and 4, a conductor pattern 128 connected to the reinforcing pattern 124 is formed in a side portion of the interconnect portion 121 of each of the first conductor pattern 211 and the second conductor pattern 212, the side portion being on an outer side in a width direction. The conductor pattern 128 prevents the flexible portion 12 from being ruptured across the interconnect portion 121.

The composite substrate 1 according to the second embodiment constituted as described above can fold the interconnect portion 121 more precisely than the boundary portion 123 between the interconnect portion 121 and the transition portion 122 even when the flexible portion 12 to be built into a casing of an electronic device is folded. Since it is constituted to be easily bent in the boundary portion 123 or the interconnect portion 121 of the flexible portion 12, no stress concentrates in the flexible portion 12 which is in the proximity of the outer peripheral edge 111 of the rigid portion 11, and the flexible portion 12 can be prevented from being folded at the outer peripheral edge 111.

Also, as shown in FIGS. 3 and 4, an edge of the soft layer 2 at each of a boundary between the outer peripheral edge 111 of the rigid portion 11 and the transition portion 122, and that between the transition portion 122 and the interconnect portion 121 is formed in a smooth curved line. Also, an angle of a portion connecting from the interconnect portion 121 to the transition portion 122 is an obtuse angle greater than a right angle. This prevents stress from concentrating at an edge of each of the interconnect portion 121 and the transition portion 122 of the flexible portion 12 when the flexible portion 12 is folded.

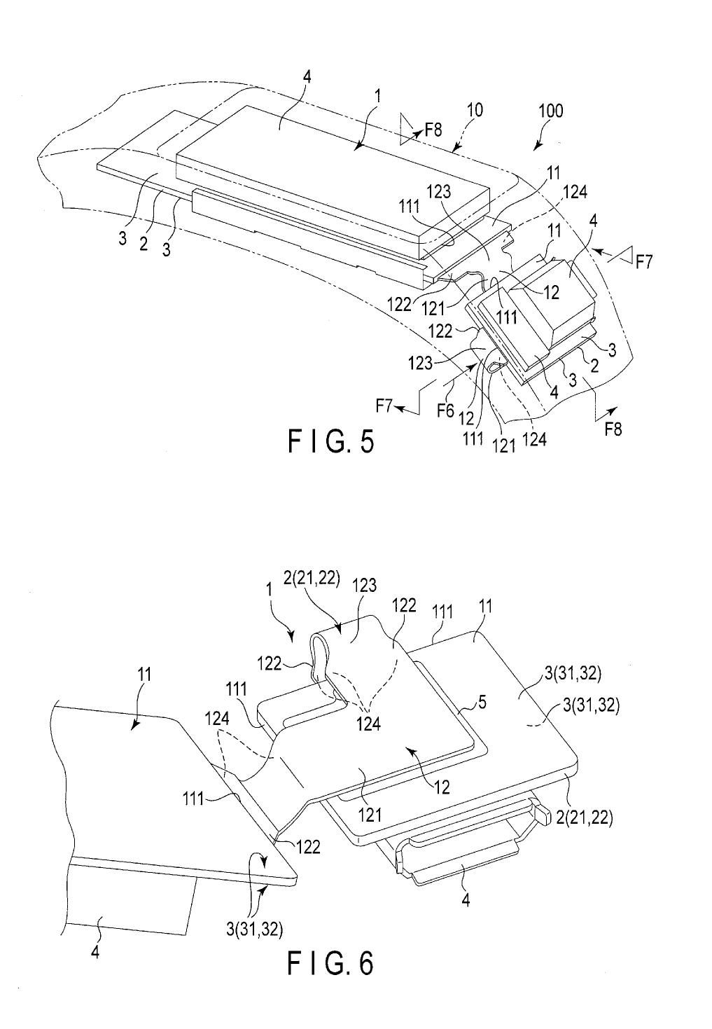

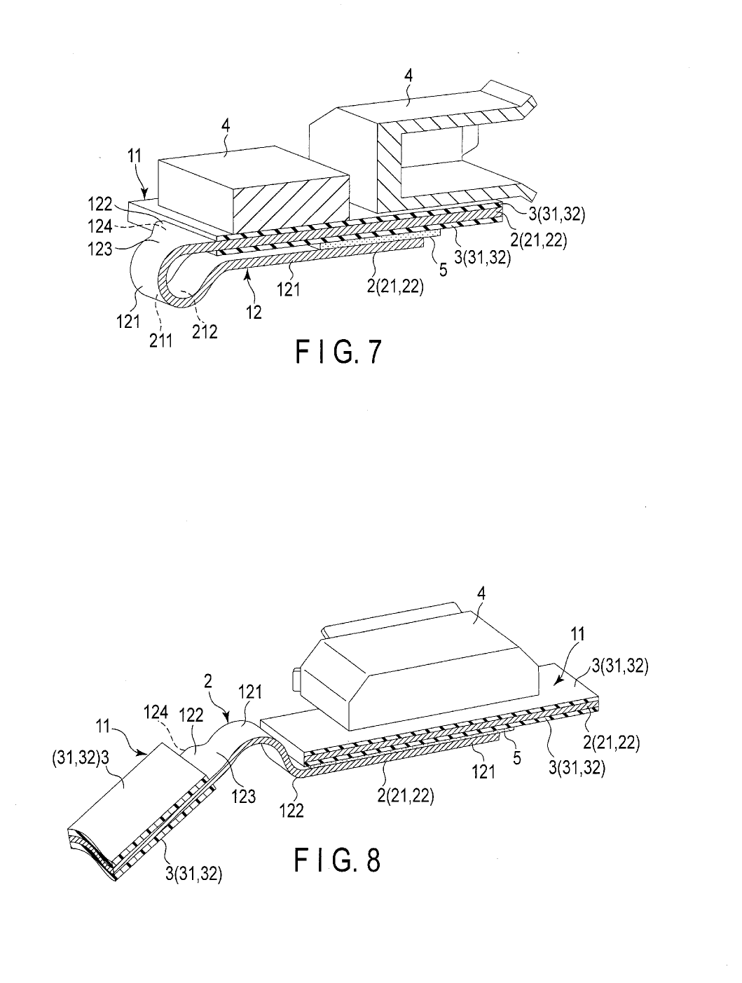

Next, the composite substrate 1 according to a third embodiment will be described with respect to FIGS. 5 to 8. FIG. 5 is a perspective view showing the composite substrate 1 accommodated in a casing bent in an arc. FIG. 6 is a perspective view showing a smaller one of the rigid portions 11 of the composite substrate 1 in FIG. 5 when seen from the rear side in the direction of arrow F6 in FIG. 5. FIG. 7 and FIG. 8 are partial sectional views of the composite substrates 1 taken along lines F7-F7 and F8-F8 in FIG. 5, respectively.

The flexible portion 12 of the composite substrate 1 according to the third embodiment is formed in a way substantially similar to the flexible portion 12 according to the second embodiment, and corresponds to a state in which the flexible portion 12 is folded to mount the composite substrate 1 according to the second embodiment on a casing 10 as an electronic device 100. In the third embodiment, in FIG. 5, the flexible portion 12 is folded in the proximity of the smaller rigid portion 11, and an elbow-shaped portion of the interconnect portion 121 of the flexible portion 12 is bonded to a side opposite to that on which an electronic component 4 is mounted on the smaller rigid portion 11 by a fixing member 5 such as double-sided tape or adhesive.

In the flexible portion 12 of the composite substrate 1 according to the third embodiment, the elbow-shaped portion is made to be wider than the bent flexible portion 12 as shown in FIG. 6. The wider portion extends to the outside of the outer peripheral edge 111 of the small rigid portion 11 as shown in FIG. 6, and comprises a function equivalent to the transition portion 122. That is, since it is wider than the interconnect portion 121 from a portion overlapping with the rigid portion 11 to a position extending to the outside of the outer peripheral edge 111, rigidity is increased and folding at an acute angle at the outer peripheral edge 111 of the rigid portion 11 is prevented.

Also, in the composite substrate 1 according to the third embodiment, as shown in FIGS. 5 to 8, regarding the flexible portion 12, the first conductor pattern 211 according to the second embodiment is located on an outer peripheral surface side of the bent portion, that is, on a side visible in FIG. 6, and the second conductor pattern 212 is located on the inside of the bent portion in FIG. 7, that is, on a side bonded to the rigid portion 11 in FIG. 6. It should be noted that if the composite substrate 1 is bent in several portions of the interconnect portion 121 as in the third embodiment, part with a small bend radius of the bent portion, and a side with a larger portion outside the bend radius in the bent portion are given priority to locate the first conductor pattern 211.

It is said that in a multi-layer flexible printed-circuit board, a risk of disconnection is higher on an inner periphery side of a curve than on an outer periphery side of the curve. Thus, the risk of disconnection potentially present in the flexible portion 12 of the soft layer 2 of the composite substrate 1 can be reduced by locating the first conductor pattern 211 on an outer peripheral surface side of the curve and locating the second conductor pattern 212 on an inner peripheral surface side of the curve as in the third embodiment.

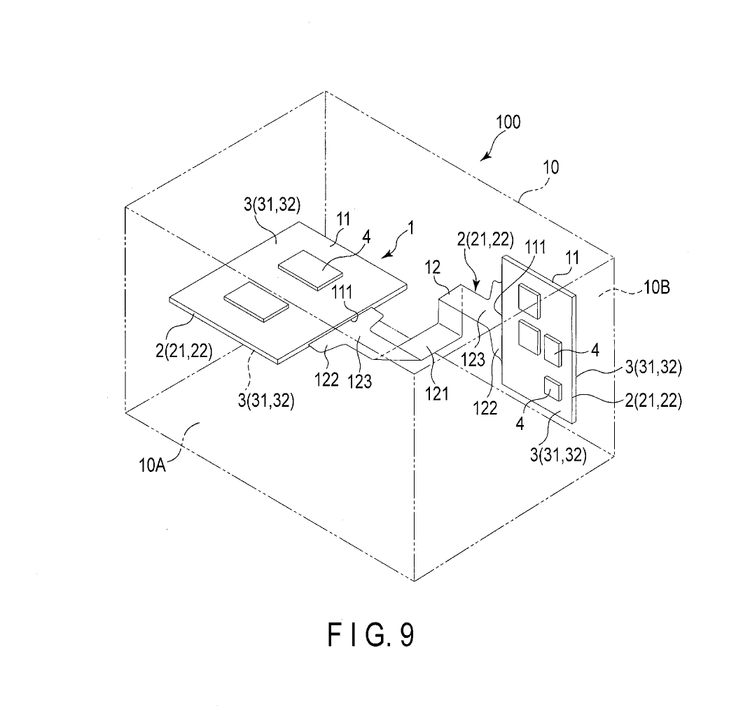

Next, the electronic device 100 according to the fourth embodiment will be described with respect to FIG. 9. The electronic device 100 comprises the composite substrate 1 shown in the first to third embodiments. Both ends of the composite substrate 1 comprise the rigid portions 11, and the flexible portion 12 connects between the rigid portions 11. The composite substrate 1 is built into the casing 10 with the flexible portion 12 folded a plurality of times in order for each of the rigid portions 11 to be along two different walls 10A and 10B of box the casing 10. At this time, in FIG. 9, all parts of the flexible portion 12 are folded in order for the first conductor pattern 211 to be located on the outer peripheral surface.

It should be noted that since the shape and size of the composite substrate 1 change depending on arrangement of the rigid portion 11, a portion through which the flexible portion 12 can pass, ease of assemble, etc., the first conductor pattern 211 is not located on the outer peripheral surface in all folded portions of the flexible portion 12. Thus, the first conductor pattern 211 can be inside a folded portion in some portion as in the third embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A composite substrate comprising:
a soft layer comprising a first conductor layer with a conductor pattern and a first flexible insulating layer;
a hard layer comprising a second conductor layer with a conductor pattern and a second rigid insulating layer;
a rigid portion in which the soft layer and the hard layer are laminated; and
a flexible portion comprising a transition portion in proximity to the rigid portion by the soft layer extending away from an outer peripheral edge of the rigid portion, the transition portion wider along the outer peripheral edge than an interconnect portion apart from the rigid portion.

2. The composite substrate of claim 1, wherein
the second rigid insulating layer covers part of the transition portion across the outer peripheral edge of the rigid portion.

3. The composite substrate of claim 1, wherein
the transition portion gradually narrows towards the interconnect portion.

4. The composite substrate of claim 1, wherein
the transition portion comprises the conductor pattern continuing from the rigid portion.

5. The composite substrate of claim 1, wherein
the soft layer of the flexible portion comprises
a first conductor pattern comprising a signal line connected to an electronic component on the rigid portion; and
a second conductor pattern laminated on the first conductor pattern and comprising a low-strength portion in the transition portion connecting to the interconnect portion with lower pattern density than the rigid portion.

6. The composite substrate of claim 1, wherein
the soft layer of the flexible portion comprises:
a first conductor pattern comprising a signal line connected to an electronic component on the rigid portion; and
a second conductor pattern laminated on the first conductor pattern, comprising conductivity throughout the interconnect portion and forming a low-strength area with lower pattern density than the rigid portion.

7. The composite substrate of claim 6, wherein
the low-strength area extends to part of the transition portion.

8. The composite substrate of claim 6, wherein
the low-strength area is a conductor pattern in a lattice shape.

9. The composite substrate of claim 6, wherein
the first conductor pattern is on an outer peripheral surface side when the flexible portion is folded.

10. An electronic apparatus comprising:
a composite substrate comprising: a soft layer comprising a first conductor layer with a conductor pattern and a first flexible insulating layer; a hard layer comprising a second conductor layer with a conductor pattern and a second rigid insulating layer; a rigid portion in which the soft layer and the hard layer are laminated; and a flexible portion comprising a transition portion formed in proximity to the rigid portion by extending the soft layer away from an outer peripheral edge of the rigid portion, the transition portion, the transition portion wider along the outer peripheral edge than an interconnect portion apart from the rigid portion; wherein
the composite substrate is folded at the flexible portion in a housing.
